(19) United States
(12) Patent Application Publication
(10) Pub. No.: US 2021/0011979 A1
(43) Pub. Date: Jan. 14, 2021

(54) Battery Emulator with Controllable Frequency Response

(71) Applicant: Apple Inc., Cupertino, CA (US)

(72) Inventors: Doug MacKay, San Jose, CA (US); Karthik Raj Kaliannan, San Jose, CA (US); Daniyal Sattarian, San Jose, CA (US)

(21) Appl. No.: 16/510,007

(22) Filed: Jul. 12, 2019

(51) Int. Cl. G06F 17/50; H03H 7/06

(52) U.S. Cl. CPC G06F 17/5009; G06F 2217/14; H03H 7/06

(57) ABSTRACT

A battery emulator can include an active voltage controlled device (VCD), one or more selectable RC filter banks, and a controller coupled to the active VCD and the one or more selectable RC filter banks. The controller may be configured to sense a load on the battery emulator and control the active VCD so as to implement a low frequency battery transfer function derived from a battery model. The controller may be further configured to control the one or more selectable RC filter banks so as to implement a high frequency battery transfer function derived from the battery model. The controller may further include a gas gauge emulation module configured to interface with a gas gauge interface of a device under test. The controller may further include a communications module configured to interface with a test host.

### BACKGROUND

People are becoming increasingly reliant on portable electronic and computing devices (hereinafter “portable electronic devices”) such as smart phones, smart watches, tablet computers, and laptop computers to meet a variety of their communication and computing needs. Such portable devices rely on battery power for their portability. As a battery ages, charges, discharges, and/or experiences varying temperatures, its internal impedance changes. These internal impedance changes may impact the battery's ability to supply large current transients. In some cases, a large current demand from an aged, cold, and/or low state of charge (“SoC”) battery can cause the voltage seen by the portable electronic device to drop below a level that triggers a brown-out or reset of the device.

Because these brown-outs or resets negatively impact the user, portable electronic device makers implement power control systems into these devices that prevent such conditions. Design and testing of such power control systems is complicated by the difficulty in providing controllable, repeatable testing under the wide variety of conditions that a portable electronic device may experience over its life cycle and/or the life cycle of its battery. As an initial matter, obtaining batteries in a variety of aging states is itself a difficult process. In some cases, a device maker may obtain new batteries and subject them to controlled aging to produce batteries in different aging states. In other cases, a device maker may take batteries from returned devices and test them to find batteries in various aging states. In either case, time and cost expenditures may be high because of the large numbers of batteries required to obtain statistically meaningful results. Additionally, even if batteries in the desired states can be obtained, the mere act of using them for testing (which requires charging and discharging) will further age the batteries, which can make it difficult to implement repeatable tests.

There have been some commercially available configurable battery emulators that attempt to address these difficulties. However, such devices have been designed around overly simplified assumptions and models regarding battery behavior. For example, such commercially available devices often include only a voltage source and a single controllable impedance. These systems are not able to adequately simulate the full range of battery performance behaviors that might be experienced by an aged or cold battery in a real application. Thus, what is needed in the art is a battery emulator that provides for enhanced fidelity to real world battery performance, particularly with regard to frequency response, as well the ability to repeatedly test certain battery states for the design and validation of battery control systems for portable electronic devices.

### SUMMARY

A battery emulator can include an active voltage controlled device, one or more selectable RC filter banks, and a controller coupled to the active voltage controlled device and the one or more selectable RC filter banks. The controller may be configured to sense a load on the battery emulator and control the active voltage controlled device responsive to the sensed load so as to implement a low frequency battery transfer function derived from a battery model. The controller may be further configured to control the one or more selectable RC filter banks responsive to the sensed load so as to implement a high frequency battery transfer function derived from the battery model. The active voltage controlled device may be a buck regulator, low dropout regulator, operational amplifier or other device. The one or more selectable RC filter banks may each include a plurality of selectable resistors and a plurality of selectable capacitors. The one or more selectable RC filter banks further comprise a configurable series resistance operable by the controller. The controller may further include a gas gauge emulation module configured to interface with a gas gauge interface of a device under test. The controller may further include a communications module configured to interface with a test host.

A method of emulating a battery can include providing an active voltage controlled device configured to implement a low frequency transfer function of a battery model. The method of emulating a battery can further include providing one or more selectable RC filter banks configured to implement a high frequency transfer function of the battery model. The method of emulating a battery can still further include monitoring a load drawn by a device under test and adjusting at least one of a performance of the active voltage controlled device and a setting of the one or more selectable RC filter banks to emulate battery performance according to the battery model. The active voltage controlled device may be an operational amplifier, a low dropout regulator, a buck regulator, or other device. The one or more selectable RC filter banks can include a plurality of selectable resistors, a plurality of selectable capacitors, and a configurable series resistance. The battery model may be derived from empirical testing, a theoretical model, or a combination thereof. A plurality of parameters corresponding to the battery module may be stored in a memory of the battery emulator. The battery model can include a plurality of impedance values associated with one or more parameters including battery age, battery condition, battery state of charge, and battery temperature.

A test setup can include a device under test and a battery emulator coupled to the device under test. The battery emulator may be configured to transparently provide power and battery management system data to the device under test, with the power being provided in accordance with a battery transfer function derived from a battery model. The test setup may further include a test host coupled to the device under test and the battery emulator. The test host may be configured to monitor data received from at least one of the device under test and the battery emulator and may be further configured to provide battery model information to the battery emulator. The battery emulator of the test setup can include an active voltage controlled device, one or more selectable RC filter banks, and a controller coupled to the active voltage controlled device and the one or more selectable RC filter banks. The controller may be configured to receive battery model information from the test host, sense a load on the battery emulator, control the active voltage controlled device responsive to the sensed load so as to implement a low frequency battery transfer function derived from the battery model information, and control the one or more selectable RC filter banks responsive to the sensed load so as to implement a high frequency battery transfer function derived from the battery model information. The controller may further include a gas gauge emulation module configured to interface with a gas gauge interface of the device under test. The battery model may include data derived from empirical testing and/or from a theoretical model. A plurality of parameters corresponding to the battery module may be stored in a memory of at least one of the test host and the battery emulator. The battery model may include a plurality of impedance values associated with one or more parameters selected from the group consisting of battery age, battery condition, battery state of charge, and battery temperature.

### BRIEF DESCRIPTION OF THE DRAWINGS

FIG. 1 depicts a battery testing system using a battery emulator as described herein.

FIG. 2 illustrates an impedance model of a battery physically implemented using a series of RC filter banks.

FIG. 3 illustrates an impedance model of a battery physically implemented by an active voltage controlled device.

FIG. 4 illustrates an impedance model of a battery broken down into a low frequency transfer function and a high frequency transfer function.

FIG. 5 illustrates a battery emulator combining an operational amplifier with a plurality of selectable RC filter banks.

FIG. 6 illustrates a battery emulator combining a buck regulator with a plurality of selectable RC filter banks.

FIG. 7 illustrates a software stack of a battery testing system.

FIG. 8 illustrates a series of different battery impedance profiles with respect to the domain of an active portion of a battery emulator and a passive portion of the battery emulator.

FIG. 9 illustrates battery emulator performance for a workload, simulating performance of a newer, better condition battery vs. an older, worse condition battery.

### DETAILED DESCRIPTION

In the following description, for purposes of explanation, numerous specific details are set forth to provide a thorough understanding of the disclosed concepts. As part of this description, some of this disclosure's drawings represent structures and devices in block diagram form for sake of simplicity. In the interest of clarity, not all features of an actual implementation are described in this disclosure. Moreover, the language used in this disclosure has been selected for readability and instructional purposes, has not been selected to delineate or circumscribe the disclosed subject matter. Rather the appended claims are intended for such purpose.

Various embodiments of the disclosed concepts are illustrated by way of example and not by way of limitation in the accompanying drawings in which like references indicate similar elements. For simplicity and clarity of illustration, where appropriate, reference numerals have been repeated among the different figures to indicate corresponding or analogous elements. In addition, numerous specific details are set forth in order to provide a thorough understanding of the implementations described herein. In other instances, methods, procedures and components have not been described in detail so as not to obscure the related relevant function being described. References to “an,” “one,” or “another” embodiment in this disclosure are not necessarily to the same or different embodiment, and they mean at least one. A given figure may be used to illustrate the features of more than one embodiment, or more than one species of the disclosure, and not all elements in the figure may be required for a given embodiment or species. A reference number, when provided in a given drawing, refers to the same element throughout the several drawings, though it may not be repeated in every drawing. The drawings are not to scale unless otherwise indicated, and the proportions of certain parts may be exaggerated to better illustrate details and features of the present disclosure.

Described herein is a battery emulator device (hereinafter, “battery emulator”). The battery emulator described herein may be used to overcome the difficulties addressed above. The battery emulator may be used in place of a power supply of a device under test with a power supply that can be programmed to emulate the impedance profile of a battery having any desired age, state of charge, temperature, etc. These impedance profiles may be derived from theoretical modeling of a particular battery, empirical testing of a population of batteries of a given type, or some combination of the two. The battery emulator may also include emulation for the battery management system (BMS) or “gas gauge” response, which can provide a device under test with BMS responses corresponding to the particular battery state, condition, and performance being emulated. Using the battery emulator as a replacement for the battery of a portable electronic device can enable testing in conditions that exceed the expected worst-case that the device will encounter in real world use. Additionally, use of a battery emulator as described herein may eliminate the need for aging cycles, recharge cycles, and temperature baths that have previously been used to replicate a desired battery. Finally, because the battery emulator may be set to consistently replicate a variety of battery conditions, broad scale analysis across repeatable conditions may be performed.

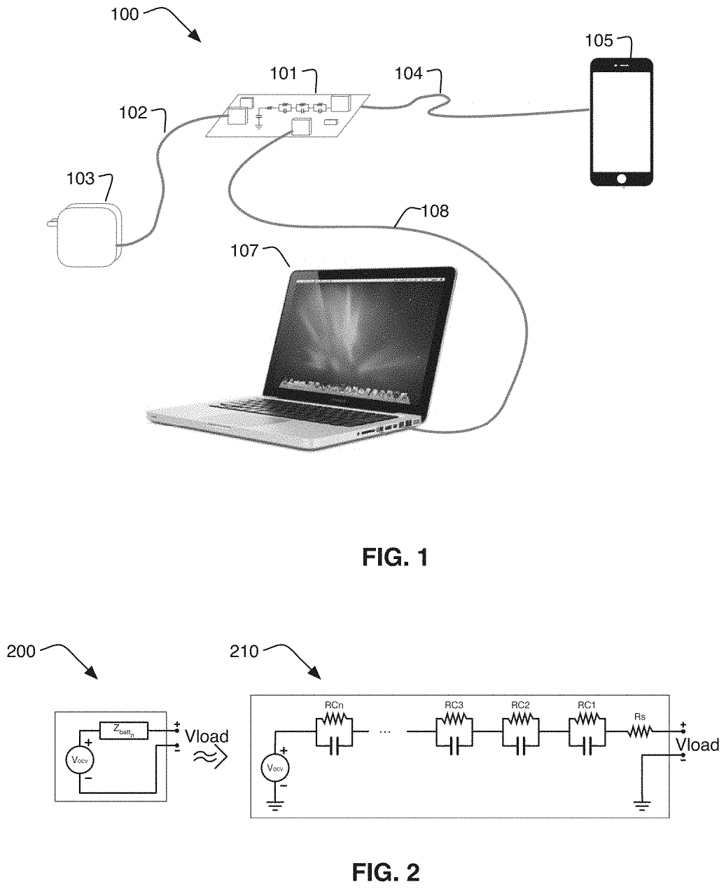

FIG. 1 illustrates an exemplary test set up 100 using a battery emulator 101. The test setup includes battery emulator 101, power supply 103, device under test 105, and test host 107. Battery emulator 101 may be implemented as described in greater detail below. Power supply 103 may be any suitable power supply that can supply adequate voltage and current to battery emulator 101 under the expected range of operating conditions. Power supply 103 may be connected to battery emulator 101 by any suitable interconnect 102. For example, in some embodiments, power supply 103 may be a USB-C/USB-PD compliant power supply, and interconnect 102 may be a corresponding USB cable. In other embodiments, any power supply and interconnect type may be used.

Device under test 105 may be a portable electronic device of interest, or, in some embodiments, may be a development board corresponding to an electronic device of interest. Device under test 105 may, in some embodiments, be a smart phone or smart watch device. It is anticipated that a battery emulator 101 of the type described herein may be particularly advantageous for testing such systems. Nonetheless, device under test 105 may also be a device including larger batteries (or a development board corresponding thereto), such as a tablet computer, notebook computer, or other portable electronic device. Device under test 105 may be coupled to battery emulator 101 by an interconnect 104. Interconnect 104 may be an interconnection cable that is designed or selected to have minimal effect on the voltage and current supplied by battery emulator 101 to device under test 105. For example, interconnect 104 may be designed so as to have negligible impedance in the range of currents and frequencies under test. Additionally, interconnect 104 may be designed to as to interface with a battery connector of portable device 105 that is or will be used in production devices. This can allow for testing of production devices using test setup 100, as well as minimizing any differences between a production battery and battery emulator 101 as seen by device under test 105.

Test host 107 may be provided to perform two broad categories of functions. First, test host 107 may be used to control battery emulator 101. To that end, test host 107 may be connected to battery emulator 101 by interconnect 108. Interconnect 108 may be any suitable interface that allows for transmission and reception of data between test host 107 and battery emulator 101. In some embodiments, test host 107 may be a general purpose computer, such as a desktop or laptop computer. In that case, interconnect 108 may be a connection between a USB port of test host 107 and a suitable interface on battery emulator 101. For example, battery emulator 101 may use a serial interface or general USB device class. In other embodiments, other communication and control protocols may be used. In any case, test host 107 may provide operating parameters to battery emulator 101 that cause it to implement a particular battery emulation state corresponding to one or more desired battery impedance profiles. Test host 107 may also collect voltage and or current data associated with a test run performed by device under test 105.

In a given real-world scenario, the behavior of power management circuitry and programming of device under test 105 may be determined by the interaction between the load generated by the device under test 105 and the battery's electrical response to that load, specifically the voltage observed by device under test 105 as a result of the battery's impedance, which is determined by the battery's age, state of charge, and temperature. The power management circuitry and programming of the device under test may thus be configured to: (1) reactively detects when the device under test is approaching a voltage droop shutdown point and force the system to reduce performance so that the device will not shut off unexpectedly; and (2) proactively set power budgets for various components within device under test 105. Both of these control aspects are directly related to the concept of voltage droop and coordinated gas gauge telemetry.

FIG. 2 illustrates a high level battery model. The battery model includes a voltage source having a voltage corresponding to an open circuit voltage (Vocv) of the battery, in series with an impedance Zbatt. This delivers an output voltage (Vload) at the battery output terminals. The output voltage appearing across the output terminals is thus given by Ohm's law. More specifically, the voltage droop may be defined as the difference between the open circuit voltage (Vocv) of the battery and the voltage seen by the load (Vload), which is a function of the voltage drop across the series impedance and the current drawn by the load. In other words:

V_{load}=V_{ocv}−V_{droop}

V_{droop}=I_{load}×Z_{batt}

V_{load}=V_{ocv}−I_{load}×Z_{batt}

Because the impedance parameter Zbatt is frequency dependent, the droop voltage is also frequency dependent. Additionally, because Zbatt is dependent upon characteristics of an electrochemical reaction (including parameters such as charge transfer, mass transfer, etc.) an equivalent circuit cannot be built from a simple combination of single passive circuit elements (i.e., a single resistor and a single capacitor).

FIG. 2 also illustrates a battery emulator made up of passive components. Battery emulator 201 can include combining one or more RC high-pass filters in series such that the sum of their impedance approximates the impedance transfer function of a target battery at a specific temperature, age, and state-of-charge. The number of RC filters selected will vary depending upon the intended application. Moreover, a unique set of R and C values may be required for each temperature, age, and state-of-charge of interest. More specifically, passive battery emulator 201 can include as a series of parallel RC circuits RC1-RCn as well as a series resistance Rs. The series resistance Rs represents the basic series resistance of the battery, with each RC circuit adding an additional battery impedance value at a particular frequency determined by the time constant of the respective RC circuit. Again, the output voltage Vload appearing at the output terminals is given by Ohm's law as described above. Alternatively, schematic 201 may be thought of as being governed by the transfer function Hbatt(s) as described below:

$${V}_{load} = {V}_{ocv} - {I}_{load} \times {H}_{batt} ( s )$$

$${H}_{batt} ( s ) \approx {\sum }_{i = 0}^{n} \frac{{R}_{i}}{1 + s \times {R}_{i} \times {C}_{i}}$$

A passive battery emulator 201 can provide an environment for repeatable testing and tuning of systems using not only batteries that are in existence but also exploration of future battery behavior and testing beyond the expected worst-case conditions. However, although an n-RC circuit for such a battery emulator is relatively straightforward, the magnitude of the capacitive components required to fully implement such a circuit with passive elements can exceed reasonable ranges. For example, capacitance values exceeding 10 kF would be required to recreate the low-frequency response of some batteries/states of interest. While the capacitive values required to emulate impedance across the full frequency spectrum exceed practical constraints, the required capacitance values are inversely proportional to frequency. As a result, the capacitance values can be kept to reasonable ranges (e.g., <<1 F) if the emulation domain is constrained to relatively high frequency ranges.

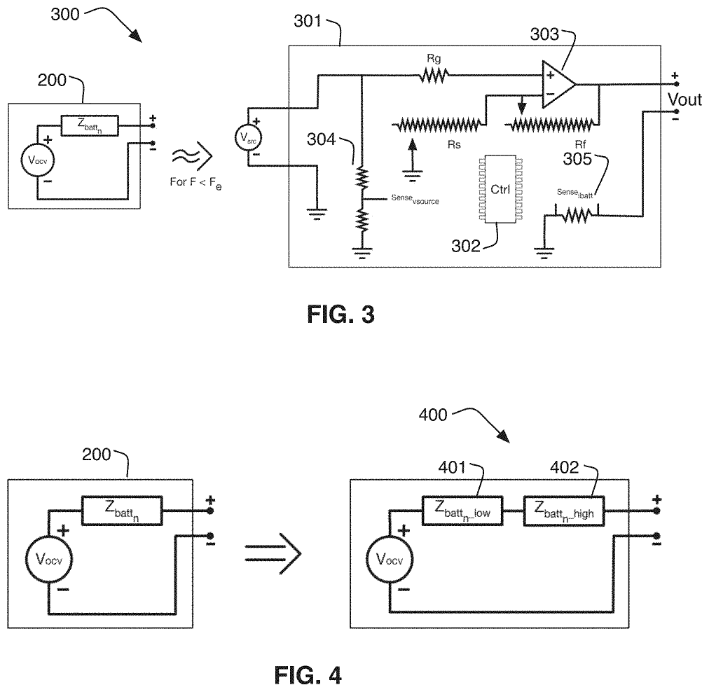

An alternative approach to implementing the battery transfer function is to implement an active voltage controlled device (“VCD”), which may be controlled by a microcontroller as illustrated in FIG. 3. In the illustrated embodiment, the active VCD 303 is an op-amp, but, depending on the specific implementation, low dropout regulators (LDOs), buck converters, or other active devices may be used as required to meet performance requirements. As illustrated in FIG. 3, a battery model 200 may be implemented as an emulator 301. Emulator 301 may be powered by a DC voltage source Vsrc. This voltage may be provided to an operational amplifier 303 (or other active voltage controlled device) that can produce a regulated output voltage Vout at the output terminals of battery emulator 301. The regulated output voltage Vout may be controlled by microcontroller 302 to match a digital model of battery performance as described in greater detail below. In the illustrated embodiment controller 302 may sense the input source voltage Vsrc via the voltage divider 304 coupled across the input side of battery emulator 301 and may sense the output current via the current resistor 305 in series with Vout. Controller 302 may adjust the regulated output voltage Vout by adjustment of digitally controlled potentiometers Rf and Rs, which may change the gain of operational amplifier 303.

Microcontroller 302 may be configured to monitor the system state and adjust the output of the VCD to match a desired battery transfer function that may be determined theoretically, empirically or by a combination thereof. The transfer function may be stored in a memory of microcontroller 302 as a computational model, a look up table, or other suitable data representation. As a result, battery emulator 301 can emulate any transfer function, but only for frequencies that fall below the bandwidth of the control loop. Above the bandwidth limit of the system (Fe), the system would be unable to measure the supplied current and alter the VCD's set-point sufficiently quickly to emulate the correct response. In some embodiments, this bandwidth limit may be 10 kHz to 1 MHz or above depending on implementation choices. In any case, implementation of this active approach must consider the granularity of adjustments required to meet the intended usage of the device. Implementations can choose to filter the output to provide gradual changes between the available discrete steps but such filters lower system bandwidth due to the latency added between the moment a voltage change is desired and when it is observed at the output. All of these design tradeoffs may be considered and adjusted for the design of any given system.

To recap, a battery emulator may be constructed of passive components, as described above with respect to FIG. 2. One potential issue with such emulators is that emulating low frequency battery response may be limited by practical concerns such as the size of capacitors required to provide the desired frequency response. Alternatively, battery emulators may be constructed of active components, as described with respect to FIG. 3. One potential issue with such emulators is the limited frequency response of the control loop and the difficulty with accurately and repeatably replicating high frequency battery response. FIG. 4 illustrates at a high level a combined approach that implements a battery model 200 as a battery emulator 400 that replicates a low frequency battery transfer function 401 and a high frequency battery transfer function 402. The transfer function for the impedance of a battery can be subdivided into two transfer functions; one targeting high-frequency response within the range of what can be practically implemented with passive circuit elements and one targeting low-frequency response that can be implemented through a VCD. The sum of these functions would be equivalent to the original transfer function. The combined transfer function of the two emulator stages may thus be given by:

H_{batt}(s)=H_{batt}_{_{high}}(s)+H_{batt}_{_{low}}(s)

where Hbatt(s) is the total transfer function, Hbatthigh(s) is a high frequency transfer function implemented by a passive emulator stage, and Hbattlow(s) is a low frequency transfer function implemented by an active emulator stage.

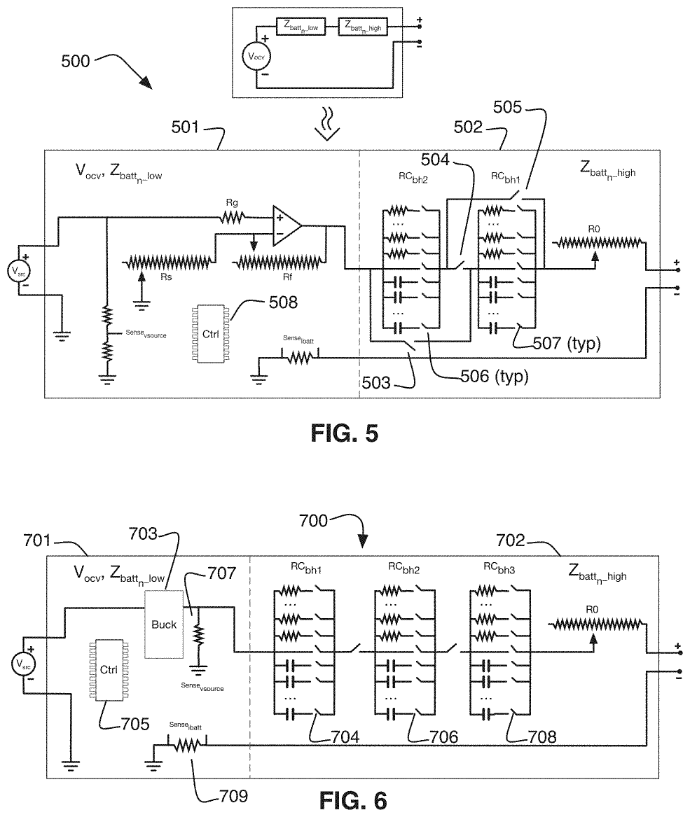

A more specific embodiment of a combined active/passive battery emulator 500 is illustrated in FIG. 5. Battery emulator 500 includes an active stage 501, corresponding to an active VCD (op-amp) based battery emulator 301 described above. Battery emulator 500 also includes a passive stage 502, corresponding to a passive RC filter based battery emulator 210 described above. By combining these two battery emulator stages, it becomes possible to implement a battery emulator that accurately and repeatably emulates battery response over a wider frequency range than either individual emulator type could provide alone.

Passive emulator stage 502 may differ from passive emulator 210 discussed above by virtue of including elements that allow selective configuration of the various RC filter stages to allow for essentially arbitrary implementation of any desired high frequency battery transfer function. For example, in the illustrated embodiment, there may be two RC filter banks RCbh1 and RCbh2, which may be used to emulate battery transfer functions in two frequency ranges, e.g., around 10 MHz and 100 MHz, respectively, although other frequency ranges may be chosen. In general any number of RC filter bank stages may be provided depending on the specific battery model transfer function(s) that is/are desired to be implemented. Switches 503, 504, and 505 allow the two RC filter banks RCbh1 and RCbh2 to be connected in series or parallel, or to be bypassed entirely depending on the particular transfer function to be implemented. Additionally, inclusion of switches 506 in RC filter bank RCbh2 and switches 507 in RC filter bank RCbh1 allow for selective combinations of resistances and capacitances to allow for fine tuning of the frequency response. Finally, passive emulator stage 502 may include a potentiometer R0 for setting the resistance of the battery emulator. Potentiometer R0 may be implemented as a digital potentiometer, so that controller 508 may have control over the resistance parameter. In fact, all of the aforementioned components (i.e., switches 503, 504, 505, 506, 507, and potentiometer R0) may be operated by controller 508 to implement a desired transfer function and associated frequency response.

To summarize, zero, one or more RC banks may be implemented depending upon the target application and the bandwidth limit (Fe) of the Zbatt_low emulation stage 501. The embodiment of FIG. 5 includes two RC banks RCbh1 and RCbh2 that may be connected in series, in parallel, or bypassed to provide (a) multiple steps above Fe when the banks are configured with unique cutoff frequencies (Fc) and/or (b) increased range or granularity when the banks are configured to target similar cutoff frequencies (Fc). For purposes of discussion, let Fe represent the bandwidth limit of the VCD control loop in stage 501, and Fp represent the lower limit of the frequency range that can be emulated by the physical RC network implementation of stage 502. To properly model the entire battery transfer function, the following rules must hold:

H_{batt}_{_{high}}(s)≈H_{batt}(s) for F>Fₑ (1)

Fₑ≥Fₚ (2)

H_{batt}_{_{low}}(s)=H_{batt}(s)−H_{batt}_{_{high}}(s) (3)

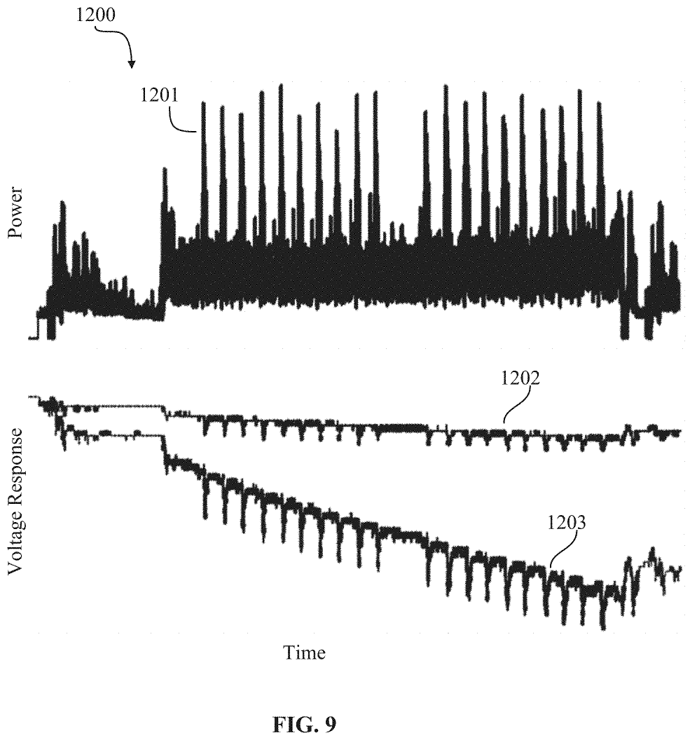

Because Fe is the upper limit of events the VCD control loop can respond to, Rule (1) states that all of the response above that frequency will be accounted for with the physical RC network. Rule (2) ensures coverage of the full frequency range. If this rule is violated, frequencies will exist between the high- and low-frequency ranges in which the system cannot emulate the desired transfer function. In some embodiments, overlap between the frequency ranges (Fe>Fp) may be desirable. Finally, Because the physical RC network emulating the high-frequency response will generate a non-zero transfer function at low frequencies equal to the sum of the resistances through the circuit, Rule (3) ensures that the sum of the high- and low-frequency portions of the design generate a transfer function equivalent to the target transfer function. FIG. 9, discussed below, illustrates a series of exemplary transfer functions and the regions in which the low frequency transfer function and high frequency function are dominant.

Because parallel RC networks act as high-pass filters, selection of RC values for a physical implementation of the high-frequency portion of the design should be based on the time-scales of interest and the amount of impedance that will need to be added at each of those time-scales. The resistance to be added for all frequencies above a given point should be selected and then a capacitance should be selected based on the cutoff frequency (Fc=R*C) of the parallel RC circuit. For example, suppose 20 mΩ of resistance must be added for all frequencies below 100 Hz. The capacitance required to precisely meet Fc=100 Hz would be 0.001 cyc/sec/0.020Ω=0.05 F. If this precise capacitance is not available, other values can be selected at the cost of shifting Fc to higher or lower frequencies. An exemplary set of resistance and capacitance values suitable for at least some embodiments is described below with respect to FIG. 11.

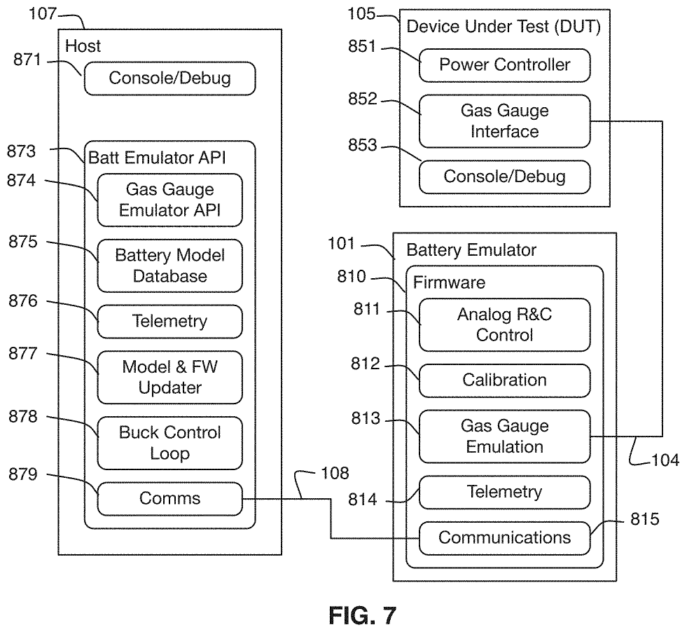

FIG. 7 illustrates an alternative embodiment of an active/passive battery emulator 700. Battery emulator 700 includes an active portion 701 based on a buck regulator and a passive portion 702 based on switchable resistor-capacitor filter banks RCbh1, RCbh2, RCbh3, and potentiometer R0. Active portion 701 may be configured to implement a low frequency transfer function of a battery model. Passive portion 702 may be configured to implement a high frequency transfer function of a battery model. In some embodiments, “low frequency” may mean battery responses slower than about 10 ms, which is well within the operating bandwidth range of conventional buck regulators, LDOs, or other voltage controlled devices. However, in addition to the responses of the active portion, it is also necessary to consider the time period (latency) required to: (1) obtain current and voltage samples, (2) perform the computations required to simulate the corresponding voltage droop (and generate the associated gas gauge telemetry), (and (3) update the voltage controlled device output voltage. Depending on the particular requirements and implementation of a given embodiment, the low frequency transfer function may include higher frequency (i.e., faster) or lower frequency (i.e., slower) responses. As discussed above, the “high frequency” portion of the battery transfer function may then correspond to responses shorter than 10 ms (or other value as appropriate), with some overlap between the two transfer function domains being potentially desirable.

The low frequency transfer function may be derived from empirical data collected from actual batteries, theoretical models of battery performance, or a combination thereof. Controller 705 may operate buck converter 703 to implement the low frequency battery transfer function by sensing (and regulating) the buck output voltage (via voltage sensor 707) and battery current (via current sense resistor 709) and programmatically adjusting the performance of buck regulator 703 accordingly. More specifically, controller 705 may be provided with battery model data in the form of look up tables, computable algorithms, or a combination thereof that allow controller to adjust the operation of buck converter 703 to produce a desired output voltage, which corresponds to the output voltage and current of the emulator 700. Voltage and current sensing are provided by sense resistors 707 and 709 in the illustrated embodiment, but other sensor types, such as Hall effect sensors for current sensing, may be used if desirable or appropriate.

As with the low frequency transfer function, the high frequency transfer function may also be derived from empirical data collected from actual batteries, theoretical models of battery performance, or a combination thereof. Controller 705 may selectively operate switches 704 (corresponding to RC filter bank RCbh1), 706 (corresponding to RC filter bank RCbh2), and 708 (corresponding to RC filter bank RCbh3) to provide a frequency dependent impedance response. Each RC bank may be used alone or in combination to provide a desired range of impedances over a given frequency window. In one embodiment, one RC filter bank may be configured to provide a range of impedance values over a relatively narrow frequency window. For example, RC filter bank RCbh1 may provide an impedance of 0-250 mΩ between 10 μs and 1 ms. The other two filter banks may be dedicated to providing a range of impedance values at over a relatively wider frequency window. For example, RC filter banks RCbh2 and RCbh3 may be configurable to provide an impedance of 0-250 mΩ between 100 μs to 10 ms. Adjustable series resistance R0, e.g., a digital potentiometer, may also be used to provide a suitable series resistance. Adjustable series resistance R0 may also be adjusted by controller 705 in accordance with its programming for a particular battery model and the sensed voltage and current. It should be understood that the foregoing impedance and time/frequency values are only exemplary and other values or ranges may be used. For example impedances substantially larger than 250 mΩ may be appropriate for some embodiments. Additionally, as the impedance increases at a given frequency, the capacitance required decreases such that a purely passive design becomes more practical.

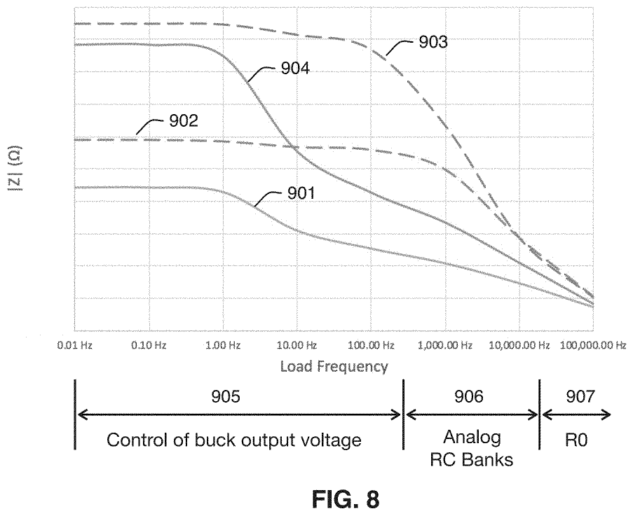

In addition to the transfer function implementation functions discussed above, controller 705 of battery emulator 700 may also implement various other functions. For example, to provide substitution of battery emulator 700 for a battery to the device under test, controller may also emulate the response of a battery management system (BMS), also colloquially known as a “gas gauge circuit.” Such battery management systems may provide information about battery condition, such as state of charge, temperature, etc., to a power control framework within the device under test. Gas gauge emulation may include information about the battery model being simulated, such as temperature and state of charge, and also the voltage and current samples that are used to simulate the battery performance and response. The gas gauge emulator may periodically update voltage, current, and related information provided to the device under test to facilitate proper operation of device under test to operate properly. Additionally, controller 705 may provide an information and interface to the test host, allowing the test host to serve as a “master controller” for battery emulation testing. These various functions may be understood with reference to FIG. 8.

FIG. 8 illustrates in block diagram form the battery emulation test setup of FIG. 1, with each component illustrating an exemplary software stack for that component. Starting with battery emulator 101, which may be built using any of the above described battery emulator topologies, a firmware layer 810 may be provided, for example in the microcontrollers described with reference to the respective topologies. Firmware 810 may provide basic device functionality and communication. More specifically firmware 810 may provide a module 811 providing control of the analog resistor and capacitor banks as described above. Firmware 810 may also provide a calibration interface 812, allowing the emulator's response to be more precisely calibrated based on the particular device tolerances used, etc. Firmware 810 may also provide a gas gauge emulation module 813, which can allow battery emulator to provide expected battery management system/gas gauge responses to device under test 105, allowing the battery emulator based testing to be transparent to the device under test. To facilitate this arrangement, gas gauge emulation layer may have a communication link to gas gauge interface 852 in device under test 105. Battery emulator firmware 810 may also include telemetry module 814, which can be configured to provide relevant data to test host 107. Finally, battery emulator firmware 810 may include communications module 815 to provide for the exchange of control and measurement data between test host 107 and battery emulator 101. Communications module 816 may thus be coupled to communications module 879 in test host 107 via communication link 108, discussed above with reference to FIG. 1.

Test host 107 may implement two main modules in its software stack. A first console/debug module 871 may provide for a console and debugging interface with a corresponding module 153 in device under test 105. This interface may be a relatively low-level interface and may be enabled by basic operating system functionality of the respective devices. Additionally, test host 107 may implement a battery emulation API 873. Battery emulation API 873 may be used by a graphical user interface application/program, a console application, a broader automation environment, or any general tool that references the battery emulator API 873. Battery emulation testing program graphical user interface 872 may provide an interface between a user/test operator of test host 107 and a battery emulator API 873. Battery emulator API 173 may provide for the various functions necessary for the user to implement a desired emulator based testing regime using battery emulator 101 and device under test 105. In some embodiments, all basic command and control may be abstracted at the API layer. Thus, higher-level applications would need little specific programming about batteries, gas gauge emulation, voltage droop, impedance profiles, or other features of the battery emulator system. The objects instantiated with battery emulator API 873 can thus encapsulate and abstract the configuration, communication, control and debug information required to operate, and even automate, the complete battery emulator system.

Battery emulator API 873 may include a gas gauge emulator API 874, which can allow the test operator to configure gas gauge emulation module 813 in battery emulator 101 to provide a desired response or responses to device under test 105. Battery emulator API 873 may also include a battery model database 875. As discussed above, this database may be based on empirical testing of batteries, theoretical models of batteries, and/or a combination thereof. Battery model database 875 may be quite expansive, providing parameters corresponding to a wide variety of battery ages (condition, number of charge/discharge cycles), conditions (full charge capacity vs. design capacity), states of charge, temperatures, etc. The parameters in battery model database 875 may be used by test host 107 to provide frequency-dependent impedance information that may be used by battery emulator 101 to implement a desired simulated battery response. Battery emulator 107 may also include telemetry module 876, which may provide for the exchange of control information and measured data between test host 107 and battery emulator 101. Telemetry exchange may take place via communications module 879 (discussed below) and interface 108.

Battery emulator API 873 may also include model and firmware updater module 877. Model and firmware updater module 877 may allow be configured to interface with battery emulator firmware 810 to configure the firmware . Module 877 can allow remote update of the firmware on the battery emulator hardware if new versions of that software/firmware are required, for example, if new features are added or bugs in the implementation are found. Configuration of the battery emulator hardware when performing a particular test or sequence of tests is performed with a combination of modules 874, 875, 811, 812 and 813 via modules 879 and 815 across interconnect 108. Once configured, dynamic voltage and gauge responses are performed during test time through a combination of modules 874, 876, 878, 813 and 814 via modules 879 and 815 across interconnect 108. Battery emulator API 873 may also include buck control loop 878. Depending on the specifics of a particular embodiment varying degrees of control of the buck converter 703 (or other active voltage controlled device in other embodiments) may be implemented by the host 107/battery emulator API 873. For example, if the controller in battery emulator 101 is a relatively low/restricted capability device the control loop may be implemented in host 107/buck control loop 878. In other embodiments in which either the battery emulator controller has a higher capability or implements a buck or other active VCD controller, then buck control loop 878 may be limited to providing configuration and/or calibration information to battery emulator 810 to control buck converter or other active VCD accordingly. In general, the control system for the battery emulator, gas gauge emulation, and other general functionality can be implemented either on the battery emulator 101 itself or on a combination of the battery emulator 101 and the host 107. Finally, battery emulator API 873 may include a communications module 879 that interfaces with a corresponding communications module 815 in battery emulator 101 via communications link 108.

In some embodiments, it may be desirable that device under test 105 implement its standard, production software stack, which need not have been specially modified or otherwise configured for battery testing. In other words, the use of battery emulator 101 to power the device and the other testing/debugging operations of host 107 may be over standard interfaces with device under test. Additionally, it is not uncommon for portable/personal electronic devices to incorporate power controllers 851 that control the device responsive to the availability and/or condition of an on board power source (such as a battery) or an external power source (not shown). Such power controllers 851 may interface with a gas gauge interface 852, which can communicate with a battery management system (BMS) or gas gauge circuit (e.g., gas gauge emulation module 813). Device under test may implement any number of other modules, which may be related to power management and battery testing. For example, there may be relatively high level power controls and relatively low level power controls configured for different functions and protection thresholds. As noted above, it is expected that a battery emulator as described herein would present to such modules as a standard battery with standard BMS circuitry and responses.

FIG. 9 illustrates a series of exemplary battery impedance profiles and the regions in which the low frequency transfer function and high frequency function are dominant. More specifically, impedance profile 901 represents an exemplary battery impedance vs. frequency for a first battery at a given temperature and state of charge. In region 905, from approximately DC (0.01 Hz) to about 200 Hz, the battery impedance profile may be controlled predominantly by the low frequency transfer function implemented by buck regulator 703 (or other active voltage controlled device) of a battery emulator. Above about 200 Hz, but below about 20 kHz, i.e., in region 906, battery impedance profile 901 may be dominated by the configuration of the analog RC filter banks described above with respect to the various battery emulator embodiments. Finally, above about 20 kHz, in region 907, battery impedance may be predominantly affected by configurable series resistance R0. Battery impedance profiles 902, 903, and 904 represent other example impedance profiles corresponding to other battery conditions, states of charge, and temperatures. However, for all of these battery impedance profiles, the predominant effect on battery impedance comes from the buck regulator (or other active VCD) in region 905, from the RC filter banks in region 906, and from the series resistance in region 907.

FIG. 12 illustrates an exemplary battery test using a battery emulator as described herein. Curve 1201 illustrates an amount of energy drawn from a battery (y-axis) as a function of time (x-axis) when implementing a particular workload, which may, for example, be any of a wide variety of standard benchmarks. Curve 1202 illustrates an exemplary battery voltage curve for the workload corresponding to an emulated battery. As can be seen, the battery voltage remains relatively constant over time. Curve 1203 illustrates an exemplary battery voltage curve for the same workload corresponding to a different set of emulated battery parameters. In this latter case, the battery voltage declines significantly with time, corresponding to an increase in the battery's internal impedance as modeled by the battery emulator. By performing tests with the same workloads corresponding to a wide variety of battery ages, conditions, states of charge, and temperature, a complete picture of device performance for different battery states may be obtained, which may be used to adapt the device's power management controllers to provide appropriate levels of performance in a wide variety of battery state regimes.

Because the battery emulators described herein are digitally controlled, adding additional features is a matter of adding suitable programming to the various software modules described above. For example, the battery emulators may be configured to emulate sinking current when a charger is connected to the device under test. Additionally, although the testing described above sets up an impedance profile for a given battery condition, the emulator may be programmed to vary battery condition and temperature throughout the tests to give a better representation of the system's dynamic response to a discharging or warming battery. Additionally, a device may be tested with emulations of different battery types to see how the device under test may respond with different batteries without having to have physical examples of the different batteries for testing.

Thus, the battery emulators described herein may include ability to programmatically define an impedance model that varies across the frequency domain. For some embodiments, this programmatic impedance model may be implemented in software to a great degree, with the physical devices (active voltage controlled devices and configurable RC filter banks) implementing the programmatic impedance during testing. Additionally, battery status, including state of charge, age, temperature, condition, etc. are all interchangeable as to how the impedance models are implemented. Thus, the battery emulator may be configured to provide for consistent and repeatable testing over any desired range of any desired battery status parameter or combination thereof. For example, a device may be tested against a battery having a variable state of charge, age, temperature, condition, or any combination thereof. Additionally, the battery emulators described herein may include the implementation of the aforementioned impedance models using a combination of active voltage controlled devices to emulate low frequency response without the requirement of excessively sized capacitors with selectable RC filter banks to emulate high frequency response to overcome control loop bandwidth issues with respect to the active voltage controlled devices.

Described above are various features and embodiments relating to programmable battery emulators. Such battery emulators may be used in a variety of applications but may be particularly advantageous when used in applications requiring consistent and repeatable testing of electronic devices to design, improve, and/or verify their performance with respect to a wide variety of battery conditions.

Although numerous specific features and various embodiments have been described, it is to be understood that, unless otherwise noted as being mutually exclusive, the various features and embodiments may be combined in any of the various permutations in a particular implementation. Thus, the various embodiments described above are provided by way of illustration only and should not be constructed to limit the scope of the disclosure. Various modifications and changes can be made to the principles and embodiments herein without departing from the scope of the disclosure and without departing from the scope of the claims.

1. A battery emulator comprising:
an active voltage controlled device;
one or more selectable RC filter banks; and
a controller coupled to the active voltage controlled device and the one or more selectable RC filter banks and configured to:
sense a load on the battery emulator;
control the active voltage controlled device responsive to the sensed load so as to implement a low frequency battery transfer function derived from a battery model; and
control the one or more selectable RC filter banks responsive to the sensed load so as to implement a high frequency battery transfer function derived from the battery model.

2. The battery emulator of claim 1 wherein the active voltage controlled device is a buck regulator.

3. The battery emulator of claim 1 wherein the active voltage controlled device is a low dropout regulator.

4. The battery emulator of claim 1 wherein the active voltage controlled device is an operational amplifier.

5. The battery emulator of claim 1 wherein the one or more selectable RC filter banks each comprise a plurality of selectable resistors and a plurality of selectable capacitors.

6. The battery emulator of claim 5 wherein the one or more selectable RC filter banks further comprise a configurable series resistance operable by the controller.

7. The battery emulator of claim 1 wherein the controller comprises a gas gauge emulation module configured to interface with a gas gauge interface of a device under test.

8. The battery emulator of claim 1 wherein the controller comprises a communications module configured to interface with a test host.

9. A method of emulating a battery, the method comprising:
providing an active voltage controlled device configured to implement a low frequency transfer function of a battery model;
providing one or more selectable RC filter banks configured to implement a high frequency transfer function of the battery model;
monitoring a load drawn by a device under test and adjusting at least one of a performance of the active voltage controlled device and a setting of the one or more selectable RC filter banks to emulate battery performance according to the battery model.

10. The method of claim 9 wherein the active voltage controlled device is selected from the group consisting of: an operational amplifier, a low dropout regulator, and a buck regulator.

11. The method of claim 9 wherein the one or more selectable RC filter banks comprise a plurality of selectable resistors, a plurality of selectable capacitors, and a configurable series resistance.

12. The method of claim 9 wherein the battery model is derived from empirical testing.

13. The method of claim 9 wherein the battery model is derived from a theoretical model.

14. The method of claim 9 wherein a plurality of parameters corresponding to the battery model are stored in a memory.

15. The method of claim 9 wherein the battery model comprises a plurality of impedance values associated with one or more parameters selected from the group consisting of:
battery age;
battery capacity;
battery composition;
battery condition;
battery state of charge; and
battery temperature.

16. A test setup comprising:
a device under test;
a battery emulator coupled to the device under test, wherein the battery emulator transparently provides power and battery management system data to the device under test, the power being provided in accordance with a battery transfer function derived from a battery model; and
a test host coupled to the battery emulator, wherein the test host is configured to monitor data received from at least one of the device under test and the battery emulator and is further configured to provide battery model information to the battery emulator.

17. The test setup of claim 16 wherein the battery emulator comprises:
an active voltage controlled device;
one or more selectable RC filter banks; and
a controller coupled to the active voltage controlled device and the one or more selectable RC filter banks and configured to:
receive battery model information from the test host;
sense a load on the battery emulator;
control the active voltage controlled device responsive to the sensed load so as to implement a low frequency battery transfer function derived from the battery model information; and
control the one or more selectable RC filter banks responsive to the sensed load so as to implement a high frequency battery transfer function derived from the battery model information.

18. The test setup of claim 17 wherein the controller further comprises a gas gauge emulation module configured to interface with a gas gauge interface of the device under test.

19. The test setup of claim 16 wherein the battery model comprises data derived from empirical testing.

20. The test setup of claim 16 wherein the battery model comprises data derived from a theoretical model.

21. The test setup of claim 16 wherein a plurality of parameters corresponding to the battery module are stored in a memory of at least one of the test host and the battery emulator.

22. The test setup of claim 16 wherein the battery model comprises a plurality of impedance values associated with one or more parameters selected from the group consisting of:
battery age;
battery capacity;
battery composition;
battery condition;
battery state of charge; and
battery temperature.
